(19) United States
(12) Patent Application Publication
(10) Pub. No.: US 2026/0049024 A1
(43) Pub. Date: Feb. 19, 2026

(54) GLASS ARTICLE, METHOD FOR MANUFACTURING THE SAME, AND DISPLAY DEVICE AND ELECTRONIC DEVICE

(71) Applicant: Samsung Display Co., LTD., Yongin-si (KR)

(72) Inventors: Hyun Seung SEO, Yongin-si (KR); Jun Ho LEE, Yongin-si (KR); Hyun Il CHO, Yongin-si (KR); Mi Jin KIM, Yongin-si (KR); Tae Ho AN, Yongin-si (KR); Sook Kyung YOU, Yongin-si (KR); Jeong Seok LEE, Yongin-si (KR)

(73) Assignee: Samsung Display Co., LTD., Yongin-si (KR)

(21) Appl. No.: 19/196,114

(22) Filed: May 1, 2025

(30) Foreign Application Priority Data
Aug. 13, 2024 (KR) 10-2024-0108328

(51) Int. Cl. C03C 10/00; H05K 5/03

(52) U.S. Cl. CPC C03C 10/0027; H05K 5/03; C03C 2204/00

(57) ABSTRACT

A glass article, a method for manufacturing the glass article, and a display device and an electronic device are provided. The glass article includes an amorphous glass layer having an amorphous phase, crystal particles dispersed in the amorphous glass layer and having a crystalline phase, and chromium ions dispersed in the amorphous glass layer.

### CROSS-REFERENCE TO RELATED APPLICATION

This application claims priority to and benefits of Korean Patent Application No. 10-2024-0108328 under 35 U.S.C. 119, filed on Aug. 13, 2024 in the Korean Intellectual Property Office, the entire contents of which are incorporated herein by reference.

### BACKGROUND

### 1. Technical Field

Embodiments relate to a glass article, a method for manufacturing the glass article, and a display device and an electronic device.

### 2. Description of the Related Art

Glass articles are widely used in electronic devices including display devices, building materials, or the like. For example, the glass articles are applied to substrates of flat panel display devices such as liquid crystal display devices (LCDs), organic light emitting display devices (OLEDs), and electrophoretic display devices, cover windows protecting the flat panel display devices, or the like.

As portable electronic devices such as smartphones and tablet personal computers (PCs) increase, glass articles applied to the portable electronic devices are also frequently exposed to an external shock. The development of glass articles capable of withstanding an external shock while being thin for portability has been required.

Recently, display devices capable of improving visibility of users have been studied. A glass article applied to a foldable display device is disposed on a display surface of the foldable display device and has an influence on visibility due to reflection of external light. Accordingly, research for improving characteristics of the glass article such as low reflectivity of external light has been demanded.

### SUMMARY

Aspects of the disclosure provide a glass article capable of improving transmissivity and reducing reflectivity of external light, and a display device and an electronic device including the display device.

However, aspects of the disclosure are not restricted to those set forth herein. The above and other aspects of the disclosure will become more apparent to one of ordinary skill in the art to which the disclosure pertains by referencing the detailed description of the disclosure given below.

According to an aspect of the disclosure, a glass article may include an amorphous glass layer having an amorphous phase, crystal particles dispersed in the amorphous glass layer and having a crystalline phase, and chromium ions dispersed in the amorphous glass layer.

In an embodiment, the amorphous glass layer may include an upper surface and a lower surface opposite to each other, and may include compressive regions disposed adjacent to the upper surface and the lower surface and a tensile region disposed between the compressive regions.

In an embodiment, the chromium ions may be disposed in the compressive regions.

In an embodiment, the compressive regions may further include sodium ions.

In an embodiment, a content of the chromium ions may form a gradient in which the content of the chromium ions decreases as being closer to the tensile region from the compressive regions.

In an embodiment, sizes of the crystal particle may be in a range of about 10 nm to about 50 nm.

In an embodiment, crystallinity may be in a range of about 50% to about 85%.

According to an aspect of the disclosure, a display device may include a display panel, and a cover window disposed on the display panel, wherein the cover window includes an amorphous glass layer having an amorphous phase, crystal particles dispersed in the amorphous glass layer and having a crystalline phase, and chromium ions dispersed in the amorphous glass layer.

In an embodiment, the amorphous glass layer may include an upper surface and a lower surface opposing the upper surface, and the amorphous glass layer may include compressive regions disposed adjacent to the upper surface and the lower surface and a tensile region disposed between the compressive regions.

In an embodiment, the chromium ions may be disposed in the compressive regions.

In an embodiment, the compressive regions may further include sodium ions.

In an embodiment, a content of the chromium ions may form a gradient in which the content of the chromium ions decreases as being closer to the tensile region from the compressive regions.

In an embodiment, sizes of the crystal particle may be in a range of about 10 nm to about 50 nm.

According to an aspect of the disclosure, an electronic device may include a display panel, and a cover window disposed on the display panel, wherein the cover window may include an amorphous glass layer having an amorphous phase, crystal particles dispersed in the amorphous glass layer and having a crystalline phase, and chromium ions dispersed in the amorphous glass layer.

The amorphous glass layer may include an upper surface and a lower surface opposing the upper surface, and the amorphous glass layer may include compressive regions disposed adjacent to the upper surface and the lower surface and a tensile region disposed between the compressive regions.

The chromium ions may be disposed in the compressive regions.

The compressive regions may further include sodium ions.

A content of the chromium ions may form a gradient in which the content of the chromium ions decreases as being closer to the tensile region from the compressive regions.

Sizes of the crystal particles may be in a range of about 10 nm to about 50 nm.

Crystallinity of the cover window may be about 50% to about 85%.

A glass article, a method for manufacturing the glass article, and a display device and an electronic device according to an embodiment may reduce reflectivity and improve transmissivity by including chromium ions through a tempering process.

The effects of the disclosure are not limited to the aforementioned effects, and various other effects are included in the specification.

### BRIEF DESCRIPTION OF THE DRAWINGS

The above and other aspects and features of the disclosure will become more apparent by describing in detail embodiments thereof with reference to the attached drawings, in which:

FIG. 1 is a schematic perspective view of glass articles according to various embodiments;

FIG. 2 is a schematic perspective view illustrating an unfolded state of a display device to which a glass article according to an embodiment is applied;

FIG. 3 is a schematic perspective view illustrating a folded state of the display device of FIG. 2;

FIG. 4 is a schematic cross-sectional view illustrating an example in which the glass article according to an embodiment is applied as a cover window of the display device;

FIG. 5 is a schematic cross-sectional view of a glass article having a flat panel plate shape according to an embodiment;

FIG. 6 is a schematic cross-sectional view illustrating the glass article according to an embodiment;

FIG. 7 is an enlarged schematic view of region A of FIG. 6;

FIG. 8 is a flowchart illustrating a method for manufacturing the glass article according to an embodiment;

FIGS. 9 to 13 are schematic cross-sectional views illustrating processes of the method for manufacturing the glass article according to an embodiment;

FIG. 14 is a graph illustrating reflectivities of glasses according to Experimental Example 1; and

FIGS. 15 and 16 are schematic perspective views illustrating application examples of electronic devices.

### DETAILED DESCRIPTION OF THE EMBODIMENTS

In the following description, for the purposes of explanation, numerous specific details are set forth in order to provide a thorough understanding of various embodiments or implementations of the invention. As used herein, “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the scope of the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element or a layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the axis of the first direction DR1, the axis of the second direction DR2, and the axis of the third direction DR3 are not limited to three axes of a rectangular coordinate system, such as the X, Y, and Z-axes, and may be interpreted in a broader sense. For example, the axis of the first direction DR1, the axis of the second direction DR2, and the axis of the third direction DR3 may be perpendicular to one another, or may represent different directions that are not perpendicular to one another. For the purposes of this disclosure, “at least one of A and B” may be understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one element's relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the invention. Further, the blocks, units, and/or modules of some embodiments may be physically combined into more complex blocks, units, and/or modules without departing from the scope of the invention.

Hereinafter, embodiments will be described with reference to the accompanying drawings.

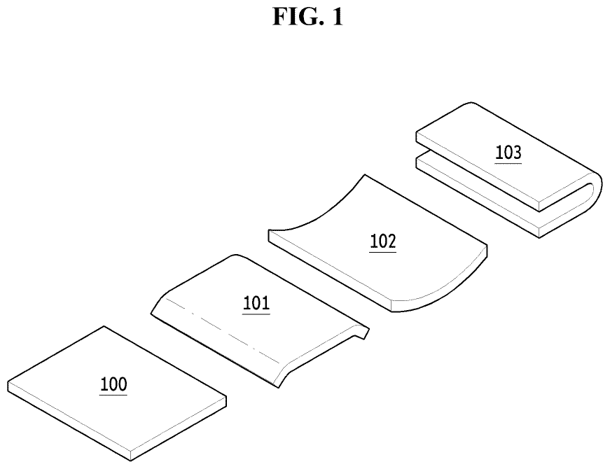

FIG. 1 is a schematic perspective view of glass articles according to various embodiments.

A glass may be used as a cover window for protecting a display device, a substrate for a display device panel, a substrate for a touch panel, an optical member such as a light guide plate, and the like, in electronic devices including display devices, such as refrigerators and washing machines including display screens, as well as tablet personal computer (PCs), laptop computers, smartphones, electronic books, televisions, PC monitors. The glass may also be used as a cover glass of instrument boards of vehicles, a cover glass for solar cells, an interior material of building materials, a window of buildings or houses, and the like.

A glass may be required to have high strength. For example, a glass for a window may have enough strength to resist external impacts and not to be readily damaged by an external shock while having a small thickness in order to satisfy requirements of high transmissivity and a light weight. A glass whose strength may be increased may be manufactured by a method such as a chemical tempering process or a thermal tempering process. Examples of tempered glasses having various shapes are illustrated in FIG. 1.

Referring to FIG. 1, in an embodiment, a glass article 100 may have a flat panel sheet or flat panel plate shape. In another embodiment, glass articles 101, 102, and 103 may each have a three-dimensional shape including a curved portion. For example, edges of a flat portion of the glass article may be curved (see ‘101’), or the glass article may be overall curved (see ‘102’) or may be folded (see ‘103’). In another example, the glass article 100 may be a foldable glass article that has a flat panel sheet or flat panel plate shape, but has flexibility, and is folded or curved. For example, the glass article 100 may be stretched or rolled.

Each of the glass articles 100 to 103 may have a rectangular shape in plan view, but is not limited thereto, and may have various shapes such as a rectangular shape with rounded corners, a square shape, a circular shape, and an elliptical shape. In the following embodiment, it will be described by way of example that each of the glass articles 100 to 103 is a flat panel plate having a rectangular shape in plan view, but embodiments are not limited thereto.

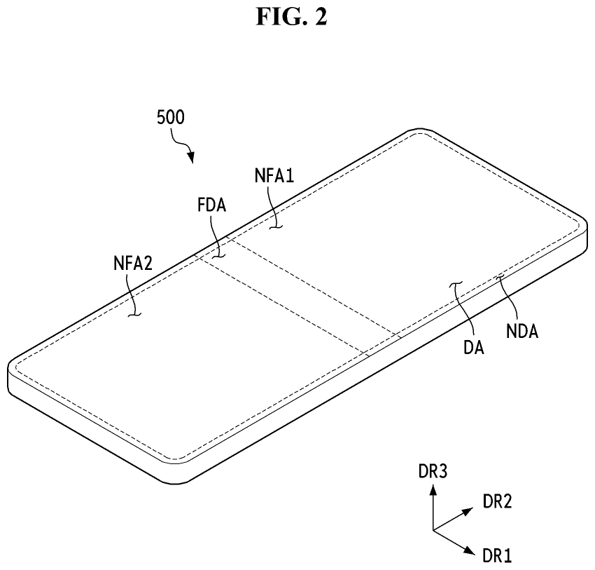

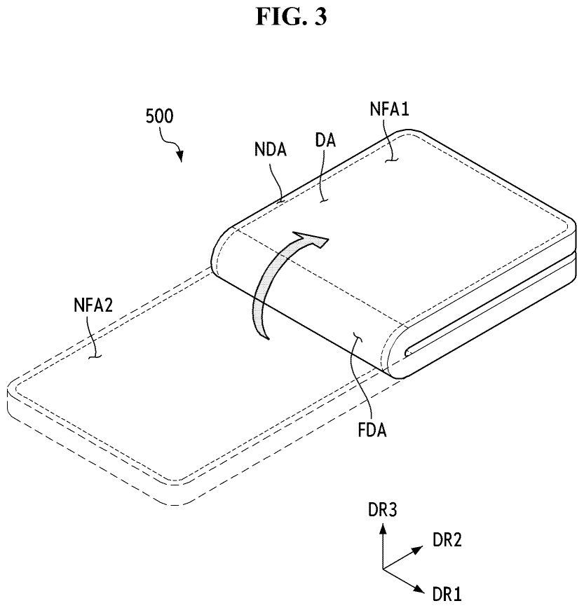

FIG. 2 is a schematic perspective view illustrating an unfolded state of a display device to which a glass article according to an embodiment is applied. FIG. 3 is a perspective view illustrating a folded state of the display device of FIG. 2.

Referring to FIGS. 2 and 3, a display device 500 according to an embodiment may be a foldable display device. As described later, in the display device 500, the glass article 100 of FIG. 1 may be applied as a cover window, and may have flexibility and be folded.

In FIGS. 2 and 3, a first direction DR1 may be a direction parallel to a side of the display device 500 in plan view, and may be, for example, a transverse direction of the display device 500. A second direction DR2 may be a direction parallel to another side of the display device 500 in contact with the side of the display device 500 in plan view, and may be a longitudinal direction of the display device 500. A third direction DR3 may be a thickness direction of the display device 500.

In an embodiment, the display device 500 may have a rectangular shape in plan view. The display device 500 may have a rectangular shape with vertical corners or a rectangular shape with rounded corners in plan view. The display device 500 may include two short sides disposed in the first direction DR1 and two long sides disposed in the second direction DR2 in plan view.

The display device 500 may include a display area DA and a non-display area NDA. In plan view, a shape of the display area DA may correspond to the shape of the display device 500. For example, in case that the display device 500 has the rectangular shape in plan view, the display area DA may also have a rectangular shape.

The display area DA may be an area displaying an image using pixels. The pixels may be arranged in a matrix direction. The plurality of pixels may have a rectangular shape, a rhombic shape, or a square shape in plan view, but are not limited thereto. For example, the pixels may have quadrangular shapes other than the rectangular shape, the rhombic shape, or the square shape, polygonal shapes other than the quadrangular shapes, a circular shape, or an elliptical shape in plan view.

The non-display area NDA may be an area that does not display an image because the non-display area NDA does not include pixels. The non-display area NDA may be disposed around the display area DA. The non-display area NDA may be disposed to surround the display area DA, but embodiments are not limited thereto. The display area DA may be partially surrounded by the non-display area NDA.

In an embodiment, the display device 500 may be maintained in both the folded state and the unfolded state. The display device 500 may be folded in an in-folding manner in which the display area DA is disposed inside as illustrated in FIG. 3. In case that the display device 500 is folded in the in-folding manner, upper surfaces of the display device 500 may be disposed to face each other. As another example, the display device 500 may be folded in an out-folding manner in which the display area DA is disposed outside. In case that the display device 500 is folded in the out-folding manner, lower surfaces of the display device 500 may be disposed to face each other.

In an embodiment, the display device 500 may be a foldable device. The term “foldable device” as used herein is a device that is foldable, and is used as the meaning including not only a folded device, but also a device that operates in both a folded state and an unfolded state. For example, folding may typically include folding at an angle of about 180°, but embodiments are not limited thereto, and in case that a folding angle exceeds about 180° or is less than about 180°, for example, about 90° or more and less than about 180° or about 120° or more and less than 180°, it may be understood that the display device is folded. For example, in case that the display device is in a bent state out of an unfolded state even though it is not completely folded, it may be referred to as the folded state. For example, even though the display device is bent at an angle of about 90° or less, as long as a maximum folding angle is about 90° or more, it may be expressed that the display device is in the folded state in order to be distinguished from the unfolded state. A radius of curvature of the display device in case of being folded may be about 5 mm or less, may be in the range of about 1 mm to about 2 mm or may be about 1.5 mm, but embodiments are not limited thereto.

In an embodiment, the display device 500 may include a folding area FDA, a first non-folding area NFA1, and a second non-folding area NFA2. The folding area FDA may be an area where the display device 500 is folded, and the first non-folding area NFA1 and the second non-folding area NFA2 may be areas where the display device 500 is not folded.

The first non-folding area NFA1 may be disposed on a side, for example, the upper side, of the folding area FDA. The second non-folding area NFA2 may be disposed on the other side, for example, the lower side, of the folding area FDA. The folding area FDA may be an area curved with a selected curvature.

In an embodiment, the folding area FDA of the display device 500 may be specified (or defined) at a specific position. The number of folding areas FDA specified at the specific position in the display device 500 may be one or two or more. In another embodiment, positions of the folding area FDA may not be specified in the display device 500, and may be freely set (or designated) in various areas.

In an embodiment, the display device 500 may be folded in the second direction DR2. For example, a length of the display device 500 in the second direction DR2 may be reduced by approximately half, and thus, a user may conveniently carry the display device 500.

In an embodiment, a direction in which the display device 500 is folded is not limited to the second direction DR2. For example, the display device 500 may be folded in the first direction DR1. For example, a length of the display device 500 in the first direction DR1 may be reduced by approximately half.

It has been illustrated in FIGS. 2 and 3 that each of the display area DA and the non-display area NDA overlaps the folding area FDA, the first non-folding area NFA1, and the second non-folding area NFA2, but embodiments are not limited thereto. For example, each of the display area DA and the non-display area NDA may overlap at least one of the folding area FDA, the first non-folding area NFA1, and the second non-folding area NFA2.

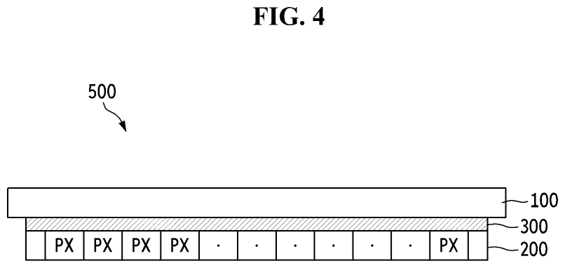

FIG. 4 is a schematic cross-sectional view illustrating an example in which the glass article according to an embodiment is applied as a cover window of the display device 500.

Referring to FIG. 4, the display device 500 may include a display panel 200, the glass article 100 disposed on the display panel 200 and serving (or functioning) as a cover window, and an optical clear coupling layer 300 disposed between the display panel 200 and the glass article 100 and coupling the display panel 200 and the glass article 100 to each other.

The display panel 200 may include, for example, not only a self-light emitting display panel such as an organic light emitting display panel (OLED), an inorganic light emitting display panel (inorganic EL), a quantum dot light emitting display panel (QED), a micro LED display panel (micro-LED), a nano LED display panel (nano-LED), a plasma display panel (PDP), a field emission display panel (FED), and a cathode ray display panel (CRT), but also a light-receiving display panel such as a liquid crystal display panel (LCD) and an electrophoretic display panel (EPD).

The display panel 200 may include pixels PX, and may display an image using light emitted from each pixel PX. The display device 500 may further include a touch member. In an embodiment, the touch member may be embedded in the display panel 200. For example, the touch member may be formed (e.g., directly formed) on a display member of the display panel 200, such that the display panel 200 itself may perform a touch function. In another embodiment, the touch member may be manufactured separately from the display panel 200 and then attached to an upper surface of the display panel 200 by the optical clear coupling layer 300.

The glass article 100 protecting the display panel 200 may be disposed above the display panel 200. The glass article 100 may have a greater size than the display panel 200, such that side surfaces of the glass article 100 may protrude outward more than side surfaces of the display panel 200, but embodiments are not limited thereto. The display device 500 may further include a printing layer disposed on at least one surface of the glass article 100 at an edge portion of the glass article 100. The printing layer may prevent a bezel area of the display device 500 from being viewed externally, and may perform a decorative function in some cases.

The optical clear coupling layer 300 may be disposed between the display panel 200 and the glass article 100. The optical clear coupling layer 300 may serve (or function) to fix the glass article 100 onto the display panel 200. The optical clear coupling layer 300 may include an optical clear adhesive (OCA), an optical clear resin (OCR), or the like.

Hereinafter, the glass article 100 described above will be described in more detail.

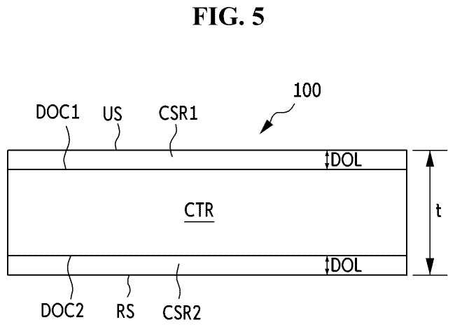

FIG. 5 is a schematic cross-sectional view of a glass article having a flat panel plate shape according to an embodiment.

Referring to FIG. 5, the glass article 100 may include a first surface US, a second surface RS, and side surfaces. In the glass article 100 having the flat panel plate shape, the first surface US and the second surface RS may be main surfaces having a great area, and the side surfaces may be outer surfaces connecting the first surface US and the second surface RS to each other.

The first surface US and the second surface RS may be opposite to each other in the thickness direction. In case that the glass article 100 serves (or functions) to transmit light like a cover window of a display, the light may mainly enter any one of the first surface US and the second surface RS and be then transmitted through the other of the first surface US and the second surface RS.

A thickness t of the glass article 100 may be defined as a distance between the first surface US and the second surface RS. The thickness t of the glass article 100 may be in the range of about 0.1 mm to about 2 mm, but embodiments are not limited thereto. In an embodiment, the thickness t of the glass article 100 may be about 0.8 mm or less. In another embodiment, the thickness t of the glass article 100 may be about 0.75 mm or less. In still another embodiment, the thickness t of the glass article 100 may be about 0.7 mm or less. In still another embodiment, the thickness t of the glass article 100 may be about 0.6 mm or less. In still another embodiment, the thickness t of the glass article 100 may be about 0.65 mm or less. In still another embodiment, the thickness t of the glass article 100 may be about 0.5 mm or less. In still another embodiment, the thickness t of the glass article 100 may be about 0.3 mm or less. In some embodiments, the thickness t of the glass article 100 may be in the range of about 0.6 mm to about 0.8 mm or in the range of about 0.69 mm to about 0.71 mm. The glass article 100 may have a uniform thickness t, but embodiments are not limited thereto, and may have a different thickness t for each region. Hereinafter, in embodiments, a glass having a thickness of about 0.70 mm will be described by way of example, but embodiments are not limited thereto.

The glass article 100 may be tempered to have a selected stress profile therein. The tempered glass article 100 may be better at preventing the occurrence and propagation of cracks, damage, and similar issues caused by external shocks as compared to the glass article 100 before being tempering. The glass article 100 tempered through a tempering process may have various stress for each region. For example, compressive regions CSR1 and CSR2 in which compressive stress acts may be disposed in the vicinity of surfaces of the glass article 100, e.g., in the vicinity of the first surface US and the second surface RS, and a tensile region CTR in which tensile stress acts may be disposed inside the glass article 100. The tensile region CTR may have an upper surface (or top surface) DOC1 and a lower surface (or bottom surface) DOC2. Stress values of boundaries between the compressive regions CSR1 and CSR2 and the tensile region CTR may be about 0. A stress value of the compressive stress in at least one of the compressive regions CSR1 and CSR2 may change according to a position (e.g., a depth from the surface). For example, the tensile region CTR may also have different stress values according to a depth from the surface US or RS. In an embodiment, a thickness of each of the compressive regions CSR1 and CSR2 formed from the surfaces of the glass article 100, for example, a compression depth DOL, may be about 150 μm or less. However, the compression depth DOL of the glass article 100 is not limited thereto.

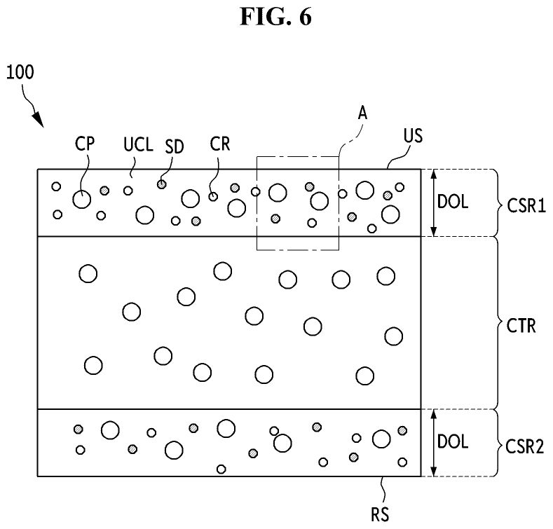

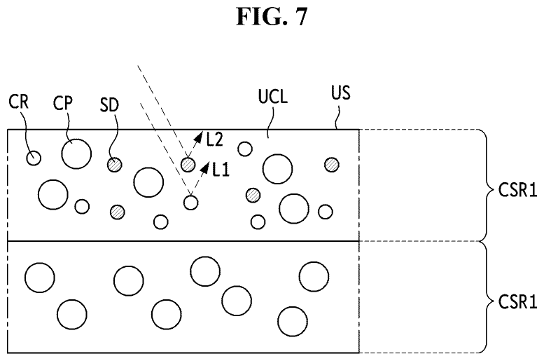

FIG. 6 is a schematic cross-sectional view illustrating the glass article according to an embodiment. FIG. 7 is an enlarged schematic view of region A of FIG. 6. For example, FIG. 7 illustrates portions of a first compressive region CSR1 and the tensile region CTR of the glass article 100.

Referring to FIGS. 6 and 7, the glass article 100 according to an embodiment may be a crystallized glass (e.g., glass-ceramics). The crystallized glass may have superior electrical, mechanical, thermal, physical, and chemical properties than a mother glass (e.g., a non-crystallized glass). The crystallized glass may be manufactured by heat-treating the mother glass as described below. It may have an advantage of improved mechanical properties and may allow a coefficient of thermal expansion (CTE) to be adjusted by adjusting (or controlling) a size of crystal particles through a heat-treating method.

The glass article 100 may include a lithium alumino silicate (LAS)-based crystallized glass or a sodium alumino silicate (SAS)-based crystallized glass. In an embodiment, the glass article 100 may include an LAS-based crystallized glass. For example, the glass article 100 may include silicon dioxide (SiO₂), aluminum oxide (Al₂O₃), and lithium oxide (Li₂O). For example, the glass article 100 may further include at least one selected from phosphorus pentoxide (P₂O₅), potassium oxide (K₂O), magnesium oxide (MgO), calcium oxide (CaO), strontium oxide (SrO), barium oxide (BaO), tin oxide (SnO₂), and zirconium oxide (ZrO₂). However, the glass article 100 is not limited thereto, and may further include other components.

In another embodiment, the glass article 100 may include silicon dioxide (SiO₂), aluminum oxide (Al₂O₃), lithium oxide (Li₂O), and sodium oxide (Na₂O). For example, the glass article 100 may further include at least one selected from phosphorus pentoxide (P₂O₅), potassium oxide (K₂O), magnesium oxide (MgO), calcium oxide (CaO), strontium oxide (SrO), barium oxide (BaO), tin oxide (SnO₂), and zirconium oxide (ZrO₂). However, the glass article 100 is not limited thereto, and may further include other components.

The glass article 100 according to an embodiment may include an amorphous glass layer UCL and crystal particles CP dispersed in the amorphous glass layer UCL. For example, the glass article 100 may include sodium ions SD and chromium ions CR dispersed in the amorphous glass layer UCL.

The amorphous glass layer UCL may be a layer formed in an amorphous phase in the glass article 100. The amorphous glass layer UCL may form an entire appearance (or profile) of the glass article 100, and may include the first surface US of the glass article 100 and the second surface RS opposing the first surface US. For example, the first surface US of the glass article 100 may be a first surface US (or an upper surface) of the amorphous glass layer UCL, and the second surface RS of the glass article 100 may be a second surface RS (or a lower surface) of the amorphous glass layer UCL.

The crystal particles CP may form a crystal phase by crystallizing a glass. The crystal phase may be, for example, a lithium disilicate crystal phase, but embodiments are not limited thereto. The crystal particles CP may be randomly dispersed and disposed in the amorphous glass layer UCL. For example, an interval (or distance) between the crystal particles CP may be random. A size of the crystal particles CP may be in a range of about 10 nm to about 50 nm. In case that the size of the crystal particles CP is about 10 nm or more, strength of the glass article 100 may be increased, and in case that the size of the crystal particles CP is about 50 nm or less, transmissivity of the glass article 100 may be prevented from being reduced.

The crystallinity of the glass article 100 may be about 50% or more. For example, the crystallinity of the glass article 100 may be about 50% to about 85%. For example, the crystallinity of the glass article 100 may be a ratio, for example, a volume ratio, of the crystal particles CP in the glass article 100. In case that the crystallinity of the glass article 100 is about 50% or more, the strength of the glass article 100 may be increased. For example, the crystallinity of the glass article 100 may be about 85% or less, and the transmissivity of the glass article 100 may be prevented from being reduced.

The amorphous glass layer UCL and the crystal particles CP of the glass article 100 may be disposed throughout the entire glass article 100. For example, the amorphous glass layer UCL and the crystal particles CP may be disposed in the compressive region CSR1 and CSR2 and the tensile region CTR of the glass article 100.

According to an embodiment, the glass article 100 may include the sodium ions (Na ions) SD and the chromium ions (Cr ions) CR. The sodium ions SD and the chromium ions CR may be disposed in the compressive regions CSR1 and SCR2 of the glass article 100. For example, the sodium ions SD and the chromium ions CR may be disposed in the first compressive region CSR1 disposed on the first surface US of the glass article 100 and a second compressive region CSR2 disposed on the second surface RS of the glass article 100.

The sodium ions SD may be included in the glass article 100 through an ion exchange process via chemical tempering to be described below. The sodium ions SD may be disposed in the compressive regions CSR1 and CSR2 of the glass article 100 through ion exchange with other ions included in the glass article 100. The sodium ions SD disposed near the surfaces of the glass article 100 may form surface compressive stress of the glass article 100.

The sodium ions SD may be randomly distributed in the compressive regions CSR1 and CSR2 of the glass article 100. In an embodiment, a content of the sodium ions SD may form a gradient in which it increases from the compressive regions CSR1 and CSR2 to the tensile region CTR.

The chromium ions CR may be included in the glass article 100 through an ion exchange process via chemical tempering to be described below. The chromium ions CR may be disposed in the compressive regions CSR1 and CSR2 of the glass article 100 through ion exchange with other ions included in the glass article 100. The chromium ions CR disposed near the surfaces of the glass article 100 may reduce the reflectivity of the glass article 100 and improve the transmissivity of the glass article 100.

The chromium ions CR may be randomly distributed in the compressive regions CSR1 and CSR2 of the glass article 100. In an embodiment, a content of the chromium ions CR may form a gradient in which it decreases from the compressive regions CSR1 and CSR2 to the tensile region CTR. For example, the content of the chromium ions CR may decrease as being closer to the tensile region CTR from the compressive regions CSR1 and CSR2. For example, the chromium ions may be disposed in the compressive regions CSR1 and CSR2 and may not be disposed in the tensile region CTR.

As described above, the chromium ions CR included in the glass article 100 may reduce the reflectivity of the glass article 100 and improve the transmissivity of the glass article 100. The chromium ions CR included in the glass article 100 may exhibit (or have) high refractive index properties, and the sodium ions SD included in the glass article 100 may exhibit (or have) low refractive index properties. In case that light is incident from the outside and reaches the first compressive region CSR1 disposed on the first surface US of the glass article 100, the light may be reflected by the chromium ions CR and the sodium ions SD. Waves of the light Li reflected by the chromium ions CR having a high refractive index and waves of the light L2 reflected by the sodium ions SD having a low refractive index may be canceled by an interference phenomenon of destructive interference. Accordingly, the reflectivity of the glass article 100 may be reduced, and the transmissivity of the glass article 100 may be improved.

Hereinafter, a method for manufacturing the glass article 100 described above will be described with reference to other drawings.

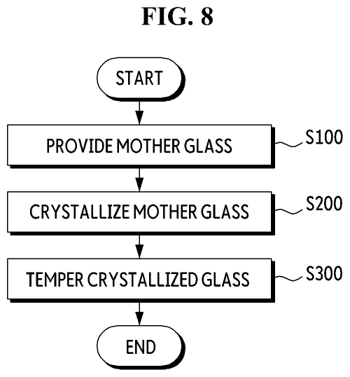

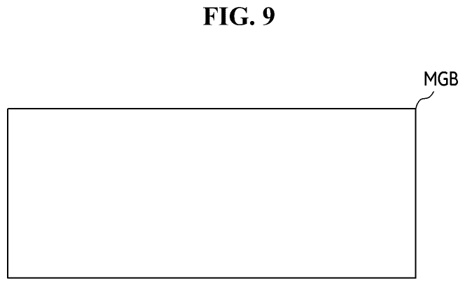

FIG. 8 is a flowchart illustrating a method for manufacturing the glass article according to an embodiment. FIGS. 9 to 13 are schematic cross-sectional views illustrating processes of the method for manufacturing the glass article according to an embodiment. In a method for manufacturing a glass article 100 to be described below, a method for manufacturing the glass article 100 illustrated in FIG. 6 described above will be described.

Referring to FIG. 8, the method for manufacturing the glass article according to an embodiment may include providing a mother glass in the step S100, crystallizing the mother glass in the step S200, and tempering the crystallized glass in the step S300.

Referring to FIG. 9 in conjunction with FIG. 8, first, the mother glass MGB may be provided in the step S100. The mother glass MGB may include a lithium alumino silicate (LAS)-based amorphous glass or a sodium alumino silicate (SAS)-based amorphous glass. The LAS-based amorphous glass may include silicon dioxide (SiO₂), aluminum oxide (Al₂O₃), and lithium oxide (Li₂O). For example, the LAS-based amorphous glass may further include at least one selected from phosphorus pentoxide (P₂O₅), potassium oxide (K₂O), magnesium oxide (MgO), calcium oxide (CaO), strontium oxide (SrO), barium oxide (BaO), tin oxide (SnO₂), and zirconium oxide (ZrO₂).

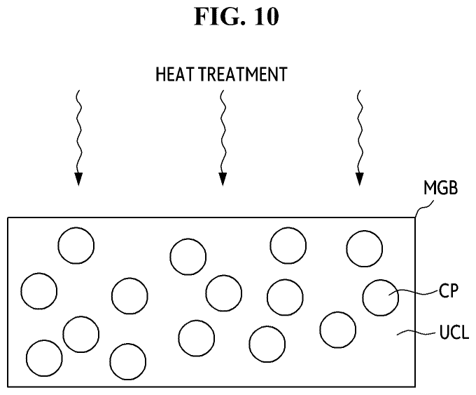

Next, referring to FIG. 10, the mother glass MGB may be crystallized in the step S200. In the crystallizing of the mother glass MGB, the mother glass MGB may be crystallized through heat treatment or laser. In an embodiment, the mother glass MGB may be crystallized through a heat treatment process. For example, the mother glass MGB may be crystallized by putting the mother glass MGB into a furnace and applying heat the mother glass MGB. The heat treatment process may be performed in a manner of raising a temperature from a room temperature to a first temperature, maintaining the first temperature for a selected time, raising a temperature from the first temperature to a second temperature, and the maintaining the second temperature for a selected time. For example, a temperature raising speed may be in the range of about 5° C./min to about 15° C./min, the first temperature may be about 500° C. to about 600° C., and the second temperature may be about 700° C. to about 800° C. A time for which the first temperature is maintained may be in the range of about 3 to about 5 hours, and a time for which the second temperature is maintained may be in the range of about 1 to about 3 hours. However, embodiments are not limited thereto.

In the heat treatment process, the mother glass MGB of an amorphous phase may be crystallized into a crystalline phase. For example, in case that the heat is applied to the mother glass MGB, portions of the mother glass MGB of the amorphous phase may be crystallized to form crystal particles CP of a crystalline phase, and the remaining portion of the mother glass MGB of the amorphous phase may be maintained in the amorphous phase to be formed as an amorphous glass layer UCL. For example, the heat treatment process may be adjusted so that a size of the crystal particles CP may be in the range of about 10 nm to about 50 nm and crystallinity may be in the range of about 50% to about 85%. Accordingly, the mother glass MGB of the amorphous phase may be formed into a crystallized glass CMB.

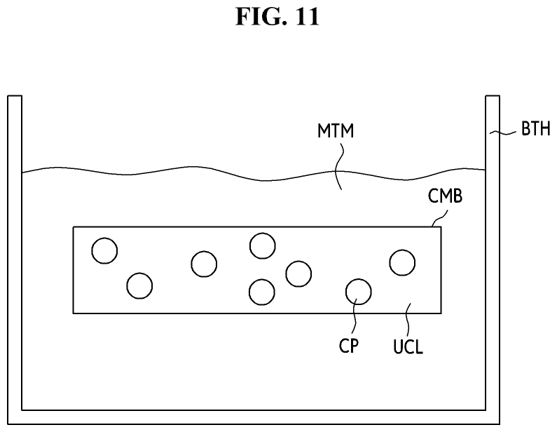

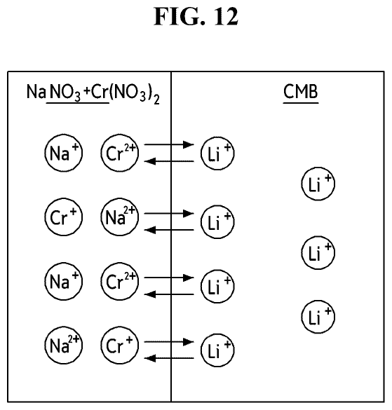

Next, referring to FIGS. 11 and 12, the crystallized glass CMB may be tempered in the step S300. The tempering of the crystallized glass may be performed by chemical tempering. In case that the glass has a small thickness of about 2 mm or less, and furthermore, about 0.75 mm or less, a chemical tempering method may be applied in order to precisely control a stress profile.

The chemical tempering may be performed through an ion exchange process. The ion exchange process may be a process of exchanging ions inside the crystallized glass CMB with other ions. Through the ion exchange process, ions on or near a surface of the crystallized glass CMB may be replaced or exchanged with greater ions having the same valence or oxidation state. For example, in case that the crystallized glass CMB includes a monovalent alkali metal such as Li⁺, Na⁺, K⁺, or Rb⁺, monovalent cations on the surface of the crystallized glass CMB may be exchanged with Na⁺, K⁺, Rb⁺, or Cs⁺ ions having a greater ionic radius than the monovalent cations.

The chemical tempering may be single-salt wet chemical tempering or mixed-salt wet chemical tempering by an immersion method. For example, the chemical tempering may be performed by immersing the crystallized glass CMB in a molten salt MTM accommodated in a bath and including an alkali metal ion salt. According to the present embodiment, mixed-salt wet chemical tempering may be used as the chemical tempering.

According to an embodiment, the crystallized glass CMB is put in a bath BTH in which the molten salt MTM is accommodated. The molten salt MTM may include sodium nitrate (NaNO₃) and chromium nitrate (Cr(NO₃)₂). The sodium nitrate (NaNO₃) may serve (or function) to provide sodium ions to the crystallized glass CMB, and the chromium nitrate (Cr(NO₃)₂) provides chromium ions to the crystallized glass CMB. In an embodiment, the molten salt MTM may include about 90 wt % to about 99 wt % of sodium nitrate (NaNO₃) and about 1 wt % to about 10 wt % of chromium nitrate (Cr(NO₃)₂). In case that a content of chromium nitrate (Cr(NO₃)₂) is about 1 wt % or more, the chromium ions may be supplied to the crystallized glass CMB to reduce the reflectivity of a final glass article and improve the transmissivity of the final glass article. For example, in case that the content of chromium nitrate (Cr(NO₃)₂) is about 10 wt % or less, the final glass article may be prevented from being colored by the chromium ions.

A tempering temperature may be in the range of about 350° C. to about 550° C. In case that the tempering temperature is about 350° C. or more, the ion exchange process may be performed, and in case that the tempering temperature is about 550° C. or less, the sodium nitrate (NaNO₃) may be prevented from being vaporized. A tempering time may be in the range of about 10 minutes to about 12 hours. In case that the tempering time is 10 minutes or more, a smooth compression depth of the final glass article may be formed, and in case that the tempering time is about 12 hours or less, a compression depth may not increase any more and may be saturated, such an unnecessary process time may be prevented. According to an embodiment, the compression depth DOL of the final glass article may be formed to be about 150 μm or less.

In case that the crystallized glass CMB is exposed to the sodium ions and the chromium ions, lithium ions inside the crystallized glass CMB may be discharged to the outside and replaced with the sodium ions and the chromium ions. The exchanged sodium ions may generate compressive stress because they have a greater ionic radius than the lithium ions. The greater the amount of the exchanged sodium ions, the greater the compressive stress. Since the ion exchange is performed through the surface of the glass, an amount of the sodium ions on the surface of the glass may be greatest. Some of the exchanged sodium ions may be diffused into the glass to increase a depth of a compressive region, in other words, the compression depth, but the amount of the exchanged sodium ions may generally decrease as a distance from the surface of the glass increases. Accordingly, the glass may have a stress profile in which the compressive stress is greatest on the surface thereof and decreases toward the inside thereof.

The exchanged chromium ions may be diffused into and disposed inside the glass, and may be disposed in the compression depth formed by the exchanged sodium ions. An amount of the exchanged chromium ions may generally decrease as a distance from the surface increases. The exchanged sodium ions may exhibit (or have) a low refractive index, and the chromium ions may exhibit (or have) a high refractive index. Accordingly, in case that external light is incident near the surface of the glass, the external light may be reflected and canceled by the sodium ions and the chromium ions, and thus, the reflectivity of the glass may be reduced and the transmissivity of the glass may be improved.

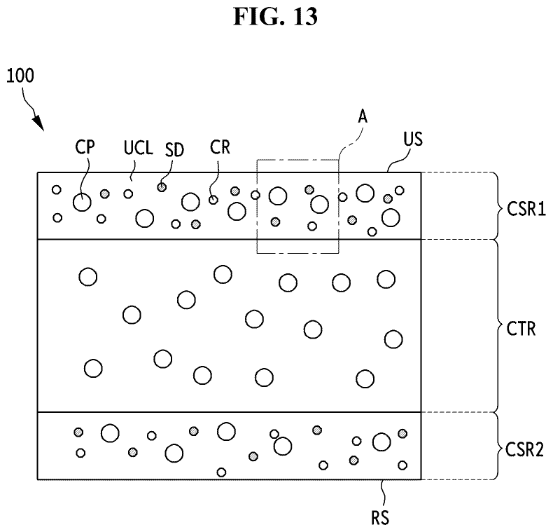

Referring to FIG. 13, the crystallized glass after the tempering process may be manufactured as a final glass article 100. The compressive region CSR1 and CSR2 and the tensile region CTR may be formed in the glass article 100. The glass article 100 according to an embodiment may include the sodium ions SD and the chromium ions CR in the compressive regions CSR1 and CSR2, such that the reflectivity of the glass article 100 may be reduced and the transmissivity of the glass article 100 may be improved.

Hereinafter, Examples will be described in more detail through Manufacturing Example and Experimental Examples.

### Manufacturing Example: Manufacturing of Tempered Glass

Plate-shaped crystallized glass substrates having a lithium alumino silicate composition were prepared, and a glass according to Comparative Example that was not subjected to a tempering process was manufactured, and Sample #A, Sample #B, Sample #C, Sample #D, and Sample #E that were respectively subjected to chemical tempering processes under different conditions were manufactured.

Sample #A was subjected to a tempering process in a bath in which a molten salt of about 100% sodium nitrate was accommodated.

Sample #B was subjected to a tempering process in a bath in which a molten salt including sodium nitrate and chromium nitrate mixed with each other in a salt ratio of 95:5 was accommodated.

Sample #C was subjected to a tempering process in a bath in which a molten salt including sodium nitrate and copper nitrate mixed with each other in a salt ratio of 95:5 was accommodated.

Sample #D was subjected to a tempering process in a bath in which a molten salt including sodium nitrate and chromium nitrate mixed with each other in a salt ratio of 99.95:0.05 was accommodated.

Sample #E was subjected to a tempering process in a bath in which a molten salt including sodium nitrate and chromium nitrate mixed with each other in a salt ratio of 99.5:0.5 was accommodated.

The tempering processes of Sample #A, Sample #B, and Sample #C were all performed at a temperature of about 450° C. for about 3 hours.

Compressive stress CS of each position in a thickness direction, compression depth DOL, and center stress CT of glasses of Sample #A and Sample #B after the tempering processes were measured using FSM-6000 and illustrated in Table 1.

TABLE 1

| | Sample#A | Sample#B |
|---|---|---|
| Compressive stress (MPa) | 419 | 419.5 |
| at 0 μm point | | |
| Compressive stress (MPa) | 261 | 269.8 |
| at 30 μm point | | |
| Compression depth (μm) | 100 | 102 |
| Center stress (MPa) | 102 | 125.9 |

Referring to Table 1, it might be confirmed that there was no significant difference in tempering characteristics according to the tempering process between Sample #A and Sample #B.

### Experimental Example 1: Evaluation of Reflectivity

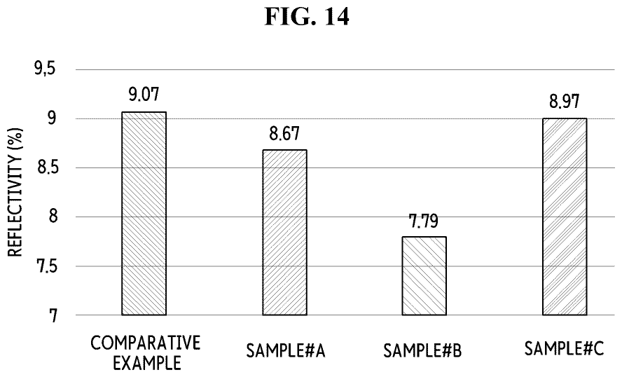

Reflectivities of glasses of Comparative Example, Sample #A, Sample #B, and Sample #C manufactured in Manufacturing Example was measured and illustrated in FIG. 14. FIG. 14 is a graph illustrating reflectivities of glasses according to Experimental Example 1.

Referring to FIG. 14, reflectivities of the glasses of Comparative Example, Sample #A, Sample #B, and Sample #C were 9.07, 8.67, 7.79, and 8.97, respectively. Comparatively, the reflectivity of Sample #B in which chromium ions were exchanged was significantly low.

Through this result, it might be confirmed that the reflectivity of the glass article in which the chromium ions were exchanged in the tempering process was reduced.

### Experimental Example 2: Evaluation of Transmissivity, Yellow Index, and Reflectivity

Transmissivities, yellow indices, and reflectivities of glasses of Sample #B, Sample #D, and Sample #E manufactured in Manufacturing Example was measured and illustrated in FIG. 2. For example, the tempering processes of Sample #B, Sample #D, and Sample #E were performed differently at a temperature of about 450° C. for about 1 hour, about 3 hours, and about 5 hours, respectively.

TABLE 2

| | Tempering | Transmissivity | Yellow | |
|---|---|---|---|---|
| # | hour | (%) | Index | Reflectivity |
| Comparative | — | 91.1 | 0.69 | 9.07 |
| Example | | | | |
| Sample#D | 1 | 91.06 | 0.73 | 9.18 |
| | 3 | 91.21 | 0.67 | 8.99 |
| | 5 | 91.28 | 0.63 | 8.98 |
| Sample#E | 1 | 91.11 | 0.7 | 9.13 |
| | 3 | 91.17 | 0.67 | 9.05 |
| | 5 | 91.17 | 0.68 | 8.99 |
| Sample#B | 1 | 92.15 | 0.4 | 7.65 |
| | 3 | 91.76 | 0.36 | 7.79 |
| | 5 | 91.9 | 0.56 | 7.91 |

Referring to Table 2, Sample #D tempered with the molten salt including the sodium nitrate and the chromium nitrate mixed with each other in the salt ratio of 99.95:0.05 exhibited a transmissivity of about about 91%, a yellow index of about 0.63 to about 0.73, and a reflectivity of about 9, and Sample #E tempered with the molten salt including the sodium nitrate and the chromium nitrate mixed with each other in the salt ratio of 99.5:0.5 exhibited a transmissivity of about 91%, a yellow index of about 0.67 to about 0.7, and a reflectivity of about 9. For example, Sample #B tempered with the molten salt including the sodium nitrate and the chromium nitrate mixed with each other in the salt ratio of 95:5 exhibited a transmissivity of about 92%, a yellow index of about 0.36 to about 0.65, and a reflectivity of about 7.

Through this result, it was confirmed that in case that the glass was tempered with the molten salt including the sodium nitrate and the chromium nitrate mixed with each other in the salt ratio of 95:5, the transmissivity was improved, the reflectivity was reduced, and the yellow index was not high, such that the glass was not colored.

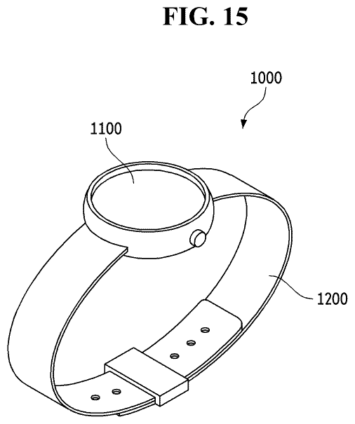

Referring to FIG. 15, the electronic device may be applied to a smart watch 1000 including a display part 1100 and a strap part 1200. The smart watch 1000 may be a wearable electronic device. For example, the smart watch 1000 may have a structure in which the strap part 1200 is mounted on a wrist of a user. The electronic device may be applied to the display part 1100, so that image data including time information can be provided to the user.

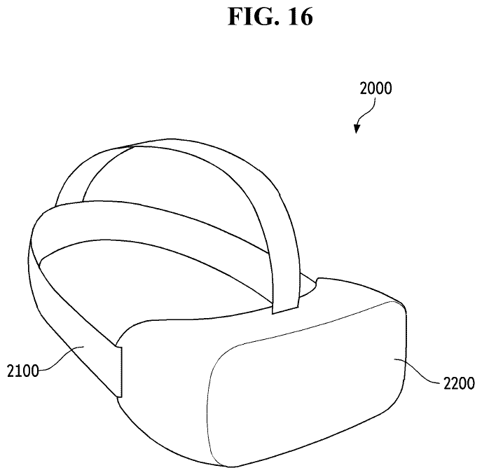

Referring to FIG. 16, the electronic device may be applied to a head mounted display device 2000. The head mounted display device 2000 may be a wearable electronic device which can be worn on the head of a user. For example, the head mounted display device 2000 may be a wearable device for virtual reality (VR) or mixed reality (MR). The head mounted display device 2000 may include a head mounted band 2100 and a display accommodating case 2200. The head mounted band 2100 may be connected to the display accommodating case 2200. The head mounted band 2100 may include a horizontal band and/or a vertical band, used to fix the head mounted display device 2000 to the head of the user. The horizontal band may be configured to surround a side portion of the head of the user, and the vertical band may be configured to surround an upper portion of the head of the user. However, embodiments are not limited thereto. For example, the head mounted band 2100 may be implemented in the form of a glasses frame, a helmet or the like within the spirit and the scope of the disclosure.

For example, the electronic device may be at least one of televisions, notebook computers, monitors, advertisement boards, Internet of things (IoTs), portable electronic apparatuses including mobile phones, smartphones, tablet personal computers (PCs), mobile communication terminals, electronic organizers, electronic books, portable multimedia players (PMPs), navigations, ultra mobile personal computers (UMPCs), smartwatches, watchphones, glasses-type displays, head-mounted displays (HMDs), instrument panels for automobiles, center fascias for automobiles, or center information displays (CIDs) on a dashboard, room mirror displays of automobiles, and displays of an entertainment system on a backside of front seats in automobiles.

As described above, the glass article according to an embodiment may reduce the reflectivity and improve the transmissivity by including the chromium ions through the tempering process.

In concluding the detailed description, those skilled in the art will appreciate that many variations and modifications can be made to the embodiments without substantially departing from the principles of the present invention. Therefore, the disclosed embodiments of the invention are used in a generic and descriptive sense only and not for purposes of limitation.

What is claimed is:

1. A glass article comprising:
an amorphous glass layer having an amorphous phase;
crystal particles dispersed in the amorphous glass layer and having a crystalline phase; and
chromium ions dispersed in the amorphous glass layer.

2. The glass article of claim 1, wherein the amorphous glass layer includes an upper surface and a lower surface opposite to each other, and includes compressive regions disposed adjacent to the upper surface and the lower surface and a tensile region disposed between the compressive regions.

3. The glass article of claim 2, wherein the chromium ions are disposed in the compressive regions.

4. The glass article of claim 2, wherein the compressive regions further include sodium ions.

5. The glass article of claim 3, wherein a content of the chromium ions forms a gradient in which the content of the chromium ions decreases as being closer to the tensile region from the compressive regions.

6. The glass article of claim 1, wherein sizes of the crystal particles are in a range of about 10 nm to about 50 nm.

7. The glass article of claim 1, wherein crystallinity is in a range of about 50% to about 85%.

8. A display device comprising:
a display panel; and
a cover window disposed on the display panel,
wherein the cover window includes:
an amorphous glass layer having an amorphous phase;
crystal particles dispersed in the amorphous glass layer and having a crystalline phase; and
chromium ions dispersed in the amorphous glass layer.

9. The display device of claim 8, wherein the amorphous glass layer includes an upper surface and a lower surface opposing the upper surface, and
the amorphous glass layer includes compressive regions disposed adjacent to the upper surface and the lower surface and a tensile region disposed between the compressive regions.

10. The display device of claim 9, wherein the chromium ions are disposed in the compressive regions.

11. The display device of claim 9, wherein the compressive regions further include sodium ions.

12. The display device of claim 10, wherein a content of the chromium ions forms a gradient in which the content of the chromium ions decreases as being closer to the tensile region from the compressive regions.

13. The display device of claim 8, wherein sizes of the crystal particles are in a range of about 10 nm to about 50 nm.

14. An electronic device comprising:
a display panel; and
a cover window disposed on the display panel,
wherein the cover window includes:
an amorphous glass layer having an amorphous phase;
crystal particles dispersed in the amorphous glass layer and having a crystalline phase; and
chromium ions dispersed in the amorphous glass layer.

15. The electronic device of claim 14, wherein the amorphous glass layer includes an upper surface and a lower surface opposing the upper surface, and
the amorphous glass layer includes compressive regions disposed adjacent to the upper surface and the lower surface and a tensile region disposed between the compressive regions.

16. The electronic device of claim 15, wherein the chromium ions are disposed in the compressive regions.

17. The electronic device of claim 15, wherein the compressive regions further include sodium ions.

18. The electronic device of claim 16, wherein a content of the chromium ions forms a gradient in which the content of the chromium ions decreases as being closer to the tensile region from the compressive regions.

19. The electronic device of claim 14, wherein sizes of the crystal particles are in a range of about 10 nm to about 50 nm.

20. The electronic device of claim 14, wherein crystallinity of the cover window is about 50% to about 85%.
